(19) United States
(12) Patent Application Publication
(10) Pub. No.: US 2023/0280914 A1
(43) Pub. Date: Sep. 7, 2023

(54) Optimizing Chia Plotting Storage and Memory Space

(71) Applicant: Western Digital Technologies, Inc., San Jose, CA (US)

(72) Inventors: Cyril GUYOT, San Jose, CA (US); Qing LI, San Jose, CA (US)

(21) Appl. No.: 18/160,974

(22) Filed: Jan. 27, 2023

Related U.S. Application Data
(60) Provisional application No. 63/315,260, filed on Mar. 1, 2022.

(51) Int. Cl. G06F 3/06

(52) U.S. Cl. CPC G06F 3/0625; G06F 3/0608; G06F 3/0679; G06F 3/0659

(57) ABSTRACT

Systems, methods, and devices described herein achieve a more efficient plotting method for proof of space cryptocurrency processes, such as the Chia cryptocurrency system. Storage devices that are configured for use with proof of space cryptocurrency processing can be configured to utilize less space within a memory array during the initial farming or plotting process. This can be done by engaging in one or more data redundancy processes during the forward propagation step of table generation. Furthermore, additional efficiency can be achieved by using a modified backward propagation method during plotting that looks back fewer steps than traditional methods. Finally, additional efficiency can be achieved by utilizing modified compression methods as well as changing the configurations of the park settings within the tables. By utilizing these modified techniques and tuning them for increased efficiency, the amount of space and resources needed to generate new cryptocurrency plots can be reduced.

### PRIORITY

This application claims the benefit of and priority to U.S. Provisional Application No. 63/315,260, entitled “Optimizing Chia Plotting Storage & Memory Space,” filed on Mar. 1, 2022, the entirety of which is being incorporated herein by reference.

### FIELD

The present disclosure relates to blockchain systems and blockchain networks. More particularly, the present disclosure relates to optimizing Chia network plotting storage and memory space.

### BACKGROUND

Storage devices are ubiquitous within computing systems. Recently, solid-state storage devices (SSDs) have become used alongside traditional magnetic storage drives. These nonvolatile storage devices can communicate and utilize various protocols including non-volatile memory express (NVMe), and peripheral component interconnect express (PCIe) to reduce processing overhead and increase efficiency.

Increasingly, these storage devices are being used within blockchain systems. Blockchain miners operate computing systems that are interconnected over a network such as the Internet and share duplicate copies of a ledger that comprises a series of data blocks that each link back to the previous block. This distributed ledger system allows for the processing of decentralized data including cryptocurrency. By utilizing various cryptographic methods on data structures shared around the network, the decentralized network can securely process data that can be relied upon for various transactions between parties. A main requirement for this to work is for the various blockchain miners on the network to all agree on using the same blockchain data. This agreement can be done through a consensus method.

Historically, the consensus method in blockchain applications was a “proof of work” consensus method. Proof of work requires that a mining computer on the blockchain network solve a series of proposed computational problems. These problems are distributed to all of the miners on the network through a challenge format. By solving the challenge, the mining computer could propose the next block to be added to the blockchain and as a reward, be issued some portion of the cryptocurrency associated with the blockchain. However, the proof of work consensus model has drawn criticism for the effects it has on the environment and the affects it has on the market for computational hardware necessary to solve the challenges.

As a result, a “proof of space” consensus method was proposed that utilizes storage space instead of computational power. Broadly, proof of space consensus involves generating and storing blockchain data on your storage device, receiving a challenge, generating an answer to that challenge utilizing the data, and providing the answer to the blockchain network for verification. The structure of the stored data and how it is processed can lead to awarding rewards in a more lottery fashion instead of awarding them to a user who has the most processing power.

The proof of space consensus mechanism (e.g., Chia plotting) can generate blockchain data used for consensus methods on a storage device but may take up a large amount of space within a memory array. Methods to generate this data focus on minimizing the size of the final blockchain data. This focus on final data size can mean that other steps within the process may be inefficient, as long as the final blockchain data product is as compact as possible.

### BRIEF DESCRIPTION OF DRAWINGS

The above, and other, aspects, features, and advantages of several embodiments of the present disclosure will be more apparent from the following description as presented in conjunction with the following several figures of the drawings.

FIG. 1A is a system diagram of a proof of space consensus blockchain system in accordance with an embodiment of the disclosure;

FIG. 1B is a conceptual block diagram of a blockchain in accordance with an embodiment of the disclosure;

FIG. 1C is a schematic block diagram of an example host-computing device with a storage system suitable for proof of space cryptocurrency processing in accordance with an embodiment of the disclosure;

FIG. 2 is a schematic block diagram of an example storage device suitable for proof of space cryptocurrency processing in accordance with an embodiment of the disclosure;

FIG. 3 is a conceptual illustration of a page of memory cells, organized for example in the NAND configuration, being sensed or programmed in parallel in accordance with an embodiment of the disclosure;

FIG. 4 is a schematic block diagram of an example blockchain data structure for proof of space cryptocurrency process in accordance with an embodiment of the disclosure;

FIG. 5 is a schematic block diagram of an example plot file in proof of space cryptocurrency process in accordance with an embodiment of the disclosure;

FIG. 6 is a schematic block diagram of two example phases of proof of space cryptocurrency process in accordance with an embodiment of the disclosure;

FIG. 7 is a schematic block diagram of an example park storage format and group park storage for proof of space cryptocurrency process in accordance with an embodiment of the disclosure;

FIG. 8 is a table of an example benchmark comparison of Asymmetric Numeral System (ANS) and Huffman for proof of space cryptocurrency process in accordance with an embodiment of the disclosure;

FIG. 9 is a table of an example plot size comparison with ANS/Huffman and different park sizes for proof of space cryptocurrency process in accordance with an embodiment of the disclosure;

FIG. 10 is a table of an example prove retrieval performance comparison for proof of space cryptocurrency process in accordance with an embodiment of the disclosure;

FIG. 11 is a table of an example comparison of final plot sizes with various parameters for proof of space cryptocurrency process in accordance with an embodiment of the disclosure;

FIG. 12 is a flowchart depicting a process for utilizing an example proof of space cryptocurrency process in accordance with an embodiment of the disclosure;

FIG. 13 is a flowchart depicting a process for generating plots more efficiently in accordance with an embodiment of the disclosure; and

FIG. 14 is a flowchart depicting a process for efficiently generating cryptocurrency tables in a proof of stake cryptocurrency system in accordance with an embodiment of the disclosure.

Corresponding reference characters indicate corresponding components throughout the several figures of the drawings. Elements in the several figures are illustrated for simplicity and clarity and have not necessarily been drawn to scale. For example, the dimensions of some of the elements in the figures might be emphasized relative to other elements for facilitating understanding of the various presently disclosed embodiments. In addition, common, but well-understood, elements that are useful or necessary in a commercially feasible embodiment are often not depicted in order to facilitate a less obstructed view of these various embodiments of the present disclosure.

### DETAILED DESCRIPTION

In response to the problems described above, devices and methods are discussed herein that can improve space and device efficiency in various proof of space cryptocurrency processes related to the generation of blockchain data (e.g., Chia plotting). For example, the plotting process can be made more space efficient during the generation of the blockchain data by using a small amount of memory to save entries of adjacent tables wherein redundant data from the table of entries are dropped while in memory during the writing process of the table of entries to the storage device. Thus, avoiding reorganizing the table of entries to remove empty storage space between adjacent table entries. In particular, this may be realized through a combined forward-backward propagation method implemented to trade-off storage space of final plots for memory space of the plotting process, thereby significantly reducing memory usage while only slightly increasing storage space usage. Further, in some embodiments, the default compression for various proof of space cryptocurrency processes (e.g., Chia plotting) can utilize a modified (i.e., improved) compression engine.

These solutions can help reduce substantial waste of bandwidth and energy from data allocation and movement between the host processor, the host memory, and the storage device. Moreover, these solutions can save memory space and increase storage space by integrating the forward and backward propagation phases into one phase. Space efficiency can be further improved by utilizing modified compression engine/methods as compression through Huffman is higher than that of ANS and decompression throughput of Huffman is comparable to that of ANS. Subsequently, the number of entries per park and the storage size for a compressed park can also be improved.

Within the Chia cryptocurrency process, there is a plotting and farming process. Plotting is the process that provers or farmers write data to disk for a given plot seed. Proving is the process that a farmer retrieves proofs meeting some requirements from disk for a given challenge. More specifically, plotting creates a plurality of tables with a number of entries within each one. In many embodiments of Chia for example, 7 tables, i.e., T₁, T₇, each with [symbol] (2^{k}) entries can be created and utilized, where k is a space parameter. In a number of embodiments, entries of T₁ are of the format (x, ƒ₁(x)), where x=0, 1, . . . , 2^{k}−1 and ƒ₁(·) is some cipher function, e.g., ChaCha8. Entries of Tᵢ can be of the form (ƒᵢ(e_{l,i-1}, e_{r,i-1}),pos, o ƒ ƒ) for i=2, 3, . . . , 7 and l, r=0, 1, . . . , 2^{k}−1, where ƒᵢ(·) is a complex encryption function, e_{l,i-1} and e_{r,i-1} are from Tᵢ₋₁ which match with each other, and pos and offset are information to locate e_{l,i-1} and e_{r,i-1}.

In a variety of embodiments, the plotting process can include a plurality of steps or phases. Phase one is often a forward propagation phase (FP). The purpose of FP is to populate T₁, . . . , T₇ where one or more matching conditions are met. For T₁, we can compute ƒ₁(x) and write to disk, e.g., for Tᵢ (i=2, 3, . . . , 7). In certain embodiments, we can first sort Tᵢ₋₁ to check the matching condition, compute ƒᵢ, and subsequently write it together with corresponding positions and collated values to disk.

In further embodiments, the second phase can be a backward propagation phase (BP). The purpose of BP is to remove data which is not useful for finding proofs so that the final plot is more space efficient. The redundant entries not forming part of the matching condition are dropped and their corresponding positions are adjusted.

In more embodiments, the third phase may be a compression step or phase. The purpose of compression is often to gain the best space efficiency for the final plots. During compression, in many embodiments, the data can first be converted from the above 2-dimensional (pus, o ƒ ƒ) format to a 1-dimensional line pointer format to achieve better compression. A fixed amount of double pointer formatted data (e.g., 2048) can be grouped as a park, and a park can be utilized as a unit of delta compression input. Currently, many traditional embodiments utilize an asymmetric numeral system (ANS) method as the compression engine.

More specifically, let e_{l,i-1} be one entry in Tᵢ, which is a match result of e_{l,i-1} and e_{r,i-1} in Tᵢ₋₁, the line pointer format of e_{l,i-1} and e_{r,i-1} is x=e_{l,i-1} (e_{l,i-1}−1)/2+e_{r,i-1}. Next, let x₁, x₂, . . . , xₘ be m sorted line pointer format data, and the delta format data is Δ₁, Δ₂, . . . , Δₘ, where Δ₁=x₁ and Δᵢ=xᵢ−xᵢ₋₁ for i=2, 3, . . . , m. Δᵢ is too large to make certain compression and decompression operations infeasible. Thus Δᵢ can be further converted to stub and delta form: (stub, delta)=(Δᵢ/n, Δᵢ% n), where n=1>>(k−2). (stub, delta) which can also be an input of the chosen compression algorithm.

These traditional plotting methods, as described above, are often space efficient in regard to the size of the final plots but is not efficient during the plotting process. For example, redundant entries, which don't lead to any matches in various tables, are not dropped until BP. This leads to a disadvantage wherein a large amount of memory or storage space is needed to store all entries in the plurality of tables during FP. For example, in some embodiments, a total memory of 416 GB may be needed for one implementation of Chia plot.

In a number of embodiments, optimization occurs during phases one and two by trading off the storage space of final plots with memory space of the plotting process. In some embodiments, this optimization can be achieved by eliminating redundant entries immediately in a combined Forward-Backward Propagation process. That is, in various embodiments, BP happens immediately after each FP and is 1-step backward, i.e., only between consecutive tables.

In many embodiments, there can be a slight trade off when utilizing a 1-step backward method compared to a 5-step backward method. Specifically, a small portion of redundant entries can remain compared to a traditional method. With the random edge assumption of the populated 2^{k} entries of Tᵢ and 1-step BP, the probability that two entries e_{l,i} and e_{r,i} are not dropped in Tᵢ is

$${p}_{1} = 1 - {( \frac{{2}^{k} - 2}{{2}^{k}} )}^{{2}^{k}} , \qquad ( 1 )$$

where in

$$( \frac{{2}^{k} - 2}{{2}^{k}} ) \qquad ( 1 )$$

is probability that e_{l,i} and e_{r,i} do not match with one particular entry of Tᵢ₊₁, and

$${( \frac{{2}^{k} - 2}{{2}^{k}} )}^{{2}^{k}}$$

is the probability that e_{l,i} and e_{r,i} do not match with any entry of Tᵢ₊₁.

Similarly, with the random edge assumption and t-step BP, the probability that two entries e_{l,i} and e_{r,i} are not dropped in Tᵢ is

$${p}_{t} = 1 - {( \frac{{2}^{k} - 2}{{2}^{k}} )}^{{p}_{t - 1}^{{2}^{k}}} , \qquad ( 2 )$$

where pₜ₋₁²^{^{k}} is the number of average entries not dropped in (t−1)-step BP, and pₜ₋₁ is the corresponding probability for (t−1)-step BP.

Therefore, theoretically with traditional 5-step backward BP methods, the number of remaining entries are:

$${2}^{k + 1} + {2}^{k} {\sum }_{t = 1}^{5} {p}_{t} = {2}^{k + 1} + {2}^{k} ( 0.865 + 0.822 + 0.807 + 0.801 + 0.798 ) = 6.09 \cdot {2}^{k} . \qquad ( 3 )$$

However, with a 1-step back BP method, the number of remaining entries are:

2^{k+1}+2^{k}·5·p₁=6.325·2^{k} (4)

Therefore, with Algorithm 2, the plot has 3.8% more redundant entries, which amounts to 3.8% more storage space required before compression. However, this can be mitigated through the use of a modified compression method.

The above predicted number, i.e., 3.8%, can be understood as the storage overhead without compression. However, naively adopting the default compression algorithm, i.e., ANS, the default park size utilized in most traditional Chia applications, and the park format can increase the plot size by upwards of 16% in certain embodiments. However, in various embodiments, techniques to optimize the final plot size via optimizing compression algorithm and the park size and format can be utilized.

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “function,” “module,” “apparatus,” or “system.” Furthermore, aspects of the present disclosure may take the form of a computer program product embodied in one or more non-transitory computer-readable storage media storing computer-readable and/or executable program code. Many of the functional units described in this specification have been labeled as functions, in order to emphasize their implementation independence more particularly. For example, a function may be implemented as a hardware circuit comprising custom VLSI circuits or gate arrays, off-the-shelf semiconductors such as logic chips, transistors, or other discrete components. A function may also be implemented in programmable hardware devices such as via field programmable gate arrays, programmable array logic, programmable logic devices, or the like.

Functions may also be implemented at least partially in software for execution by various types of processors. An identified function of executable code may, for instance, comprise one or more physical or logical blocks of computer instructions that may, for instance, be organized as an object, procedure, or function. Nevertheless, the executables of an identified function need not be physically located together but may comprise disparate instructions stored in different locations which, when joined logically together, comprise the function and achieve the stated purpose for the function.

Indeed, a function of executable code may include a single instruction, or many instructions, and may even be distributed over several different code segments, among different programs, across several storage devices, or the like. Where a function or portions of a function are implemented in software, the software portions may be stored on one or more computer-readable and/or executable storage media. Any combination of one or more computer-readable storage media may be utilized. A computer-readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object-oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to”, unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Further, as used herein, reference to reading, writing, storing, buffering, and/or transferring data can include the entirety of the data, a portion of the data, a set of the data, and/or a subset of the data. Likewise, reference to reading, writing, storing, buffering, and/or transferring non-host data can include the entirety of the non-host data, a portion of the non-host data, a set of the non-host data, and/or a subset of the non-host data.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps, or acts are in some way inherently mutually exclusive.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

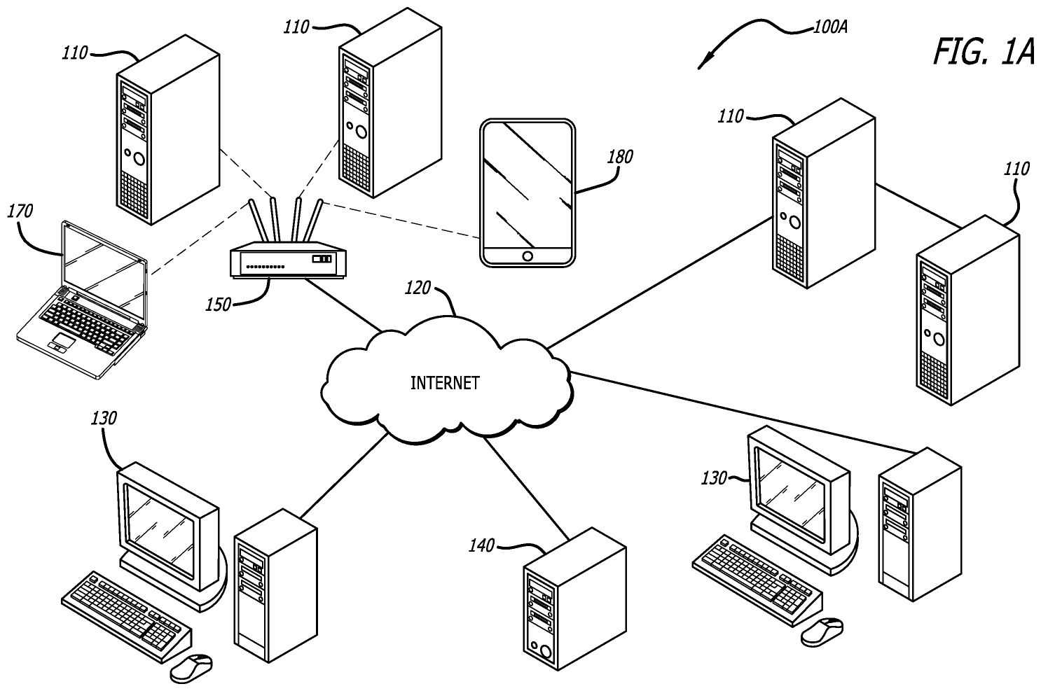

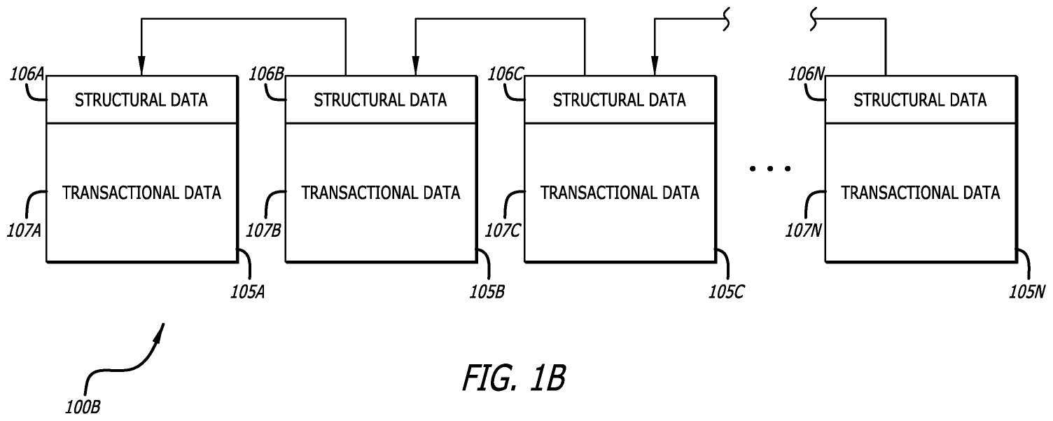

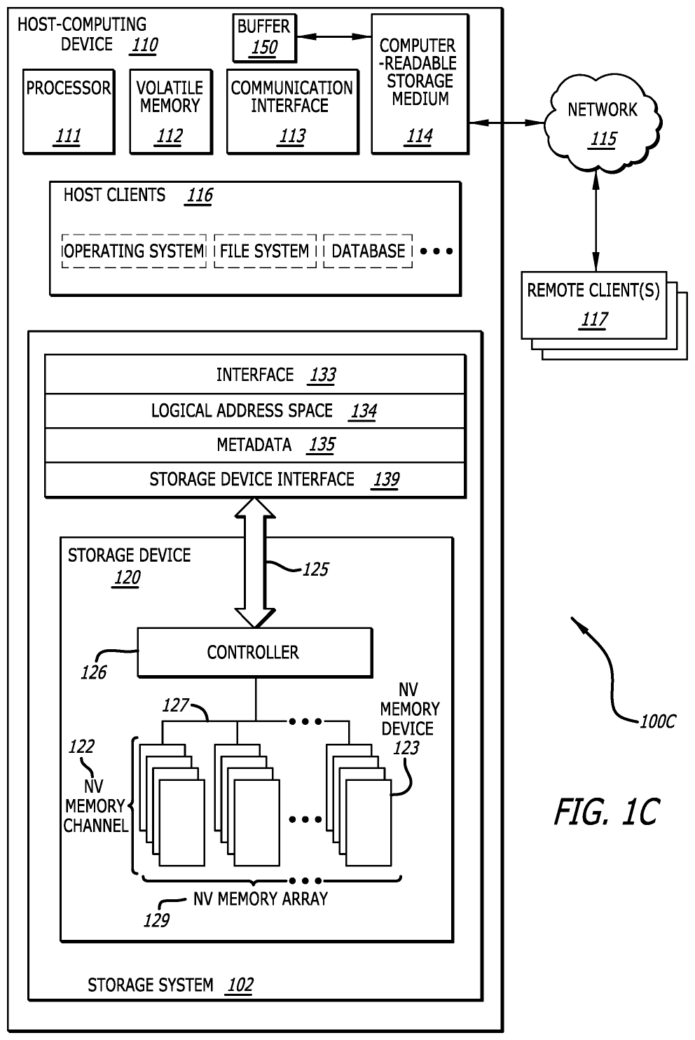

Referring to FIG. 1A, a system diagram of a proof of space consensus blockchain system 100A in accordance with an embodiment of the invention is shown. The proof of space consensus blockchain system 100A often comprises a series of nodes which may be a host-computing device 110 that executes a Chia client application or other logic. For example, in the Chia blockchain network, the nodes include farmers and timelords. These nodes transmit and receive data related to the proof of space consensus blockchain across various networks such as the Internet 120. While embodiments of the present disclosure may encompass any viable proof of space blockchain system, the embodiments described throughout the figures will be related to the Chia blockchain network. Therefore, it should be understood that certain embodiments described herein can be applied to other non-Chia networks as needed.

In many embodiments, various host-computing devices 110 may be connected to the Internet 120 and each other. These host-computing device 110 may act as Chia node servers and communicate or transmit Chia blockchain data between each other. In addition, there may be additional types of devices that may act as farmers and/or timelords. Personal computers operated by individual and/or remote users may have applications that act as personal computer Chia nodes 130 which may also be connected to and communicate with the other host-computing devices 110 and other Chia nodes. In some instances, a specialized device may be connected to the network that acts as a Chia timelord 140 which typically assists in validation processes.

Furthermore, connection to the network via nodes can be made wirelessly through one or more wireless access points 150 which may connect a variety of devices including more Chia node servers, portable Chia node servers 170, or personal electronic device Chia servers 180. It should be recognized by those skilled in the art that Chia node devices may come in any available form factor and that the minimum requirements are that a processor, network connection, and storage space for completed plots be present. While it is most profitable to remain connected to the proof of space consensus blockchain system 100 at all times, it should be understood that node devices may leave or connect intermittently, temporarily, or permanently.

Referring to FIG. 1B, a conceptual block diagram of a blockchain 100B is shown. A blockchain 100B can be understood as a growing list of blocks which comprise records or other data. These blocks are linked together through various methods that typically involve cryptography. In many instances, each block 105A-105N (with the exception of the first, or genesis, block 105A) will comprise structural data 106A-106N including a hash related to the previous block, a timestamp, and some sort of transactional data 107A-107N.

Because each non-genesis block 105B-105N refers back to the previous block, the blockchain 100B itself becomes tamper-resistant. A network of computing devices acting as nodes each keep a copy of this blockchain 100B on their systems as a distributed ledger. This structure keeps blockchain ledgers from having a centralized controller and are thus decentralized. Thus, they have grown in popularity over the past decade and have been applied to a variety of applications such as cryptocurrency.

A major issue with blockchain systems is how the nodes all agree on what the next block in the blockchain should be. This issue is called “consensus” and can be solved in a number of ways. For example, Bitcoin utilizes blockchains and a “proof of work” consensus method. This method involves a lot of computational power from CPUs and GPUs of the various nodes. Another emerging consensus method is a “proof of space” method, such as the one utilized on the Chia network, which instead of utilizing computations to solve challenge problems, storage space is required to prove that data has been held by the node. This data is called proof of space data and can be generated within a storage device. Discussion of this process in more detail is outlined below.

Referring to FIG. 1C, a schematic block diagram of an example host-computing device 110 with a storage system 102 suitable for proof of space cryptocurrency processing (e.g., Chia plotting) in accordance with an embodiment of the disclosure is shown. The proof of space cryptocurrency processing system 100 comprises one or more storage devices 120 of a storage system 102 within a host-computing device 110 in communication via a controller 126. The host-computing device 110 may include a processor 111, volatile memory 112, and a communication interface 113. The processor 111 may include one or more central processing units, one or more general-purpose processors, one or more application-specific processors, one or more virtual processors (e.g., the host-computing device 110 may be a virtual machine operating within a host), one or more processor cores, or the like. The communication interface 113 may include one or more network interfaces configured to communicatively couple the host-computing device 110 and/or controller 126 of the storage device 120 to a communication network 115, such as an Internet Protocol (IP) network, a Storage Area Network (SAN), wireless network, wired network, or the like.

The storage device 120, in various embodiments, may be disposed in one or more different locations relative to the host-computing device 110. In one embodiment, the storage device 120 comprises one or more non-volatile memory devices 123, such as semiconductor chips or packages or other integrated circuit devices disposed on one or more printed circuit boards, storage housings, and/or other mechanical and/or electrical support structures. For example, the storage device 120 may comprise one or more direct inline memory module (DIMM) cards, one or more expansion cards and/or daughter cards, a solid-state-drive (SSD) or other hard drive device, and/or may have another memory and/or storage form factor. The storage device 120 may be integrated with and/or mounted on a motherboard of the host-computing device 110, installed in a port and/or slot of the host-computing device 110, installed on a different host-computing device 110 and/or a dedicated storage appliance on the network 115, in communication with the host-computing device 110 over an external bus (e.g., an external hard drive), or the like.

The storage device 120, in one embodiment, may be disposed on a memory bus of a processor 111 (e.g., on the same memory bus as the volatile memory 112, on a different memory bus from the volatile memory 112, in place of the volatile memory 112, or the like). In a further embodiment, the storage device 120 may be disposed on a peripheral bus of the host-computing device 110, such as a peripheral component interconnect express (PCI Express or PCIe) bus such, as but not limited to a NVM Express (NVMe) interface, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the storage device 120 may be disposed on a communication network 115, such as an Ethernet network, an Infiniband network, SCSI RDMA over a network 115, a storage area network (SAN), a local area network (LAN), a wide area network (WAN) such as the Internet, another wired and/or wireless network 115, or the like.

The host-computing device 110 may further comprise computer-readable storage medium 114. The computer-readable storage medium 114 may comprise executable instructions configured to cause the host-computing device 110 (e.g., processor 111) to perform steps of one or more of the methods disclosed herein. Additionally, or in the alternative, the buffering component 150 may be embodied as one or more computer-readable instructions stored on the computer-readable storage medium 114.

A device driver and/or the controller 126, in certain embodiments, may present a logical address space 134 to the host clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

A device driver for the storage device 120 may maintain metadata 135, such as a logical to physical address mapping structure, to map logical addresses of the logical address space 134 to media storage locations on the storage device(s) 120. A device driver may be configured to provide storage services to one or more host clients 116. The host clients 116 may include local clients operating on the host-computing device 110 and/or remote clients 117 accessible via the network 115 and/or communication interface 113. The host clients 116 may include, but are not limited to: operating systems, file systems, database applications, server applications, kernel-level processes, user-level processes, applications, and the like.

In many embodiments, the host-computing device 110 can include a plurality of virtual machines which may be instantiated or otherwise created based on user-request. As will be understood by those skilled in the art, a host-computing device 110 may create a plurality of virtual machines configured as virtual hosts which is limited only on the available computing resources and/or demand. A hypervisor can be available to create, run, and otherwise manage the plurality of virtual machines. Each virtual machine may include a plurality of virtual host clients similar to host clients 116 that may utilize the storage system 102 to store and access data.

The device driver may be further communicatively coupled to one or more storage systems 102 which may include different types and configurations of storage devices 120 including, but not limited to: solid-state storage devices, semiconductor storage devices, SAN storage resources, or the like. The one or more storage devices 120 may comprise one or more respective controllers 126 and non-volatile memory channels 122. The device driver may provide access to the one or more storage devices 120 via any compatible protocols or interface 133 such as, but not limited to, SATA and PCIe. The metadata 135 may be used to manage and/or track data operations performed through the protocols or interfaces 133. The logical address space 134 may comprise a plurality of logical addresses, each corresponding to respective media locations of the one or more storage devices 120. The device driver may maintain metadata 135 comprising any-to-any mappings between logical addresses and media locations.

A device driver may further comprise and/or be in communication with a storage device interface 139 configured to transfer data, commands, and/or queries to the one or more storage devices 120 over a bus 125, which may include, but is not limited to: a memory bus of a processor 111, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The storage device interface 139 may communicate with the one or more storage devices 120 using input-output control (IO-CTL) command(s), IO-CTL command extension(s), remote direct memory access, or the like.

The communication interface 113 may comprise one or more network interfaces configured to communicatively couple the host-computing device 110 and/or the controller 126 to a network 115 and/or to one or more remote clients 117 (which can act as another host). The controller 126 is part of and/or in communication with one or more storage devices 120. Although FIG. 1 depicts a single storage device 120, the disclosure is not limited in this regard and could be adapted to incorporate any number of storage devices 120.

The storage device 120 may comprise one or more non-volatile memory devices 123 of non-volatile memory channels 122, which may include but is not limited to: ReRAM, Memristor memory, programmable metallization cell memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like. The one or more non-volatile memory devices 123 of the non-volatile memory channels 122, in certain embodiments, comprise storage class memory (SCM) (e.g., write in place memory, or the like).

While the non-volatile memory channels 122 is referred to herein as “memory media,” in various embodiments, the non-volatile memory channels 122 may more generally comprise one or more non-volatile recording media capable of recording data, which may be referred to as a non-volatile memory medium, a non-volatile memory device, or the like. Further, the storage device 120, in various embodiments, may comprise a non-volatile recording device, a non-volatile memory array 129, a plurality of interconnected storage devices in an array, or the like.

The non-volatile memory channels 122 may comprise one or more non-volatile memory devices 123, which may include, but are not limited to: chips, packages, planes, die, or the like. A controller 126 may be configured to manage data operations on the non-volatile memory channels 122, and may comprise one or more processors, programmable processors (e.g., FPGAs), ASICs, micro-controllers, or the like. In some embodiments, the controller 126 is configured to store data on and/or read data from the non-volatile memory channels 122, to transfer data to/from the storage device 120, and so on.

The controller 126 may be communicatively coupled to the non-volatile memory channels 122 by way of a bus 127. The bus 127 may comprise an I/O bus for communicating data to/from the non-volatile memory devices 123. The bus 127 may further comprise a control bus for communicating addressing and other command and control information to the non-volatile memory devices 123. In some embodiments, the bus 127 may communicatively couple the non-volatile memory devices 123 to the controller 126 in parallel. This parallel access may allow the non-volatile memory devices 123 to be managed as a group, forming a non-volatile memory array 129. The non-volatile memory devices 123 may be partitioned into respective logical memory units (e.g., logical pages) and/or logical memory divisions (e.g., logical blocks). The logical memory units may be formed by logically combining physical memory units of each of the non-volatile memory devices 123.

The controller 126 may organize a block of word lines within a non-volatile memory device 123, in certain embodiments, using addresses of the word lines, such that the word lines are logically organized into a monotonically increasing sequence (e.g., decoding and/or translating addresses for word lines into a monotonically increasing sequence, or the like). In a further embodiment, word lines of a block within a non-volatile memory device 123 may be physically arranged in a monotonically increasing sequence of word line addresses, with consecutively addressed word lines also being physically adjacent (e.g., WL0, WL1, WL2, . . . WLN).

The controller 126 may comprise and/or be in communication with a device driver executing on the host-computing device 110. A device driver may provide storage services to the host clients 116 via one or more interfaces 133. A device driver may further comprise a storage device interface 139 that is configured to transfer data, commands, and/or queries to the controller 126 over a bus 125, as described above.

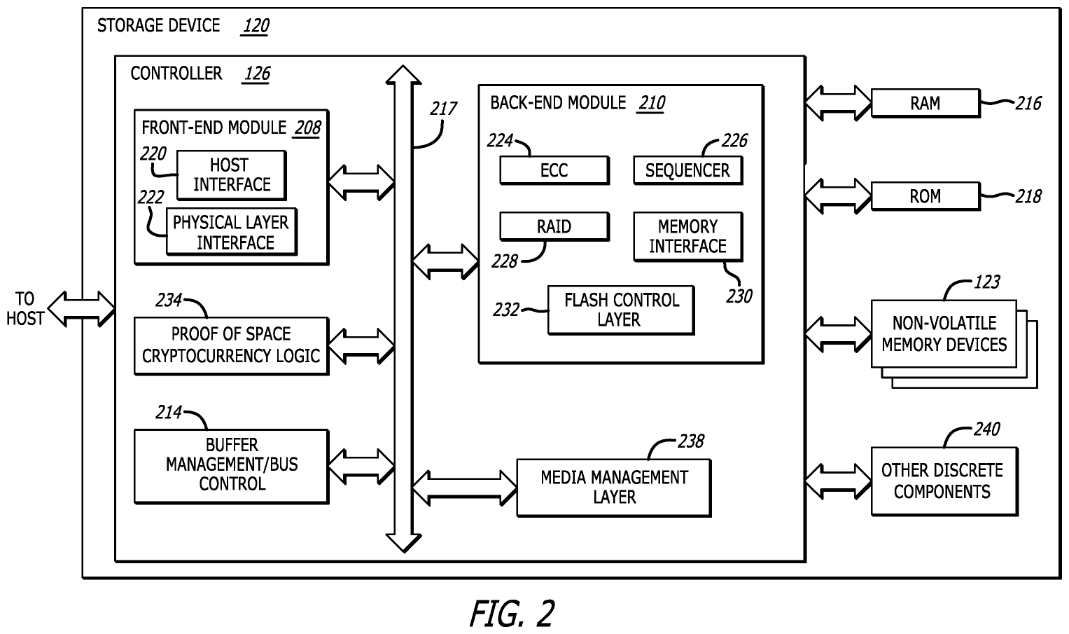

Referring to FIG. 2, a schematic block diagram of an example storage device 120 suitable for proof of space cryptocurrency processing in accordance with various embodiments of the disclosure is shown. The controller 126 may include a front-end module 208 that interfaces with a host via a plurality of high priority and low priority communication channels, a back-end module 210 that interfaces with the non-volatile memory devices 123, and various other modules that perform various functions of the storage device 120. In some examples, each module may just be the portion of the memory that comprises instructions executable with the processor to implement the features of the corresponding module without the module including any other hardware. Because each module includes at least some hardware even when the included hardware comprises software, each module may be interchangeably referred to as a hardware module.

The controller 126 may include a buffer management/bus control module 214 that manages buffers in random access memory (RAM) 216 and controls the internal bus arbitration for communication on an internal communications bus 217 of the controller 126. A read only memory (ROM) 218 may store and/or access system boot code. Although illustrated in FIG. 2 as located separately from the controller 126, in other embodiments one or both of the RAM 216 and the ROM 218 may be located within the controller 126. In yet other embodiments, portions of RAM 216 and ROM 218 may be located both within the controller 126 and outside the controller 126. Further, in some implementations, the controller 126, the RAM 216, and the ROM 218 may be located on separate semiconductor dies. As discussed below, in one implementation, the submission queues and the completion queues may be stored in a controller memory buffer, which may be housed in RAM 216.

Additionally, the front-end module 208 may include a host interface 220 and a physical layer interface 222 that provides the electrical interface with the host or next level storage controller. The choice of the type of the host interface 220 can depend on the type of memory being used. Example types of the host interfaces 220 may include, but are not limited to, SATA, SATA Express, SAS, Fibre Channel, USB, PCIe, and NVMe. The host interface 220 may typically facilitate transfer for data, control signals, and timing signals.

The back-end module 210 may include an error correction controller (ECC) engine 224 that encodes the data bytes received from the host and decodes and error corrects the data bytes read from the non-volatile memory devices 123. The back-end module 210 may also include a command sequencer 226 that generates command sequences, such as program, read, and erase command sequences, to be transmitted to the non-volatile memory devices 123. Additionally, the back-end module 210 may include a RAID (Redundant Array of Independent Drives) module 228 that manages generation of RAID parity and recovery of failed data. The RAID parity may be used as an additional level of integrity protection for the data being written into the storage device 120. In some cases, the RAID module 228 may be a part of the ECC engine 224. A memory interface 230 provides the command sequences to the non-volatile memory devices 123 and receives status information from the non-volatile memory devices 123. Along with the command sequences and status information, data to be programmed into and read from the non-volatile memory devices 123 may be communicated through the memory interface 230. A flash control layer 232 may control the overall operation of back-end module 210.

Additional modules of the storage device 120 illustrated in FIG. 2 may include a media management layer 238, which performs wear leveling of memory cells of the non-volatile memory devices 123. The storage device 120 may also include other discrete components 240, such as external electrical interfaces, external RAM, resistors, capacitors, or other components that may interface with controller 126. In alternative embodiments, one or more of the RAID modules 228, media management layer 238 and buffer management/bus control module 214 are optional components that may not be necessary in the controller 126.

Finally, the controller 126 may also comprise a proof of space cryptocurrency logic 234 that can be configured to allocate, populate, process, write and plot data for table of entries, groups of entries, and other data needed to perform proof of space cryptocurrency processing (e.g., Chia plotting). In many embodiments, the proof of space cryptocurrency logic 234 can be utilized by the controller 126 to attempt to perform various operations that facilitate various proof of space cryptocurrency processing operations as described herein within the disclosure. This can include, but is not limited to, accessing control data stored within the storage device 120, scanning the non-volatile memory devices 123 for data to allocate, populate, process, write and plot data for table of entries, groups of entries, and other data, and then continuing (or directing the controller 126 to continue) the proof of space cryptocurrency processing operations. In further embodiments, the proof of space cryptocurrency logic 234 can carry out processes similar to the processes discussed in more detail within FIGS. 1A-1C and 3-14.

Each of the non-volatile memory devices 123 may include data for proof of storage cryptocurrency processing. The proof of storage cryptocurrency processing data may be distributed evenly within each of one or more non-volatile memory devices 123. In some embodiments, non-volatile memory devices 123 may be grouped into a plurality of sets, where each set of non-volatile memory devices 123 provides a specific proof of storage cryptocurrency processing instruction, instruction set, and/or data set. Moreover, each set of non-volatile memory devices 123 may comprise the same or different feature data and feature vector store. The controller 126 may then pass the query vector to one or more relevant non-volatile memory devices 123.

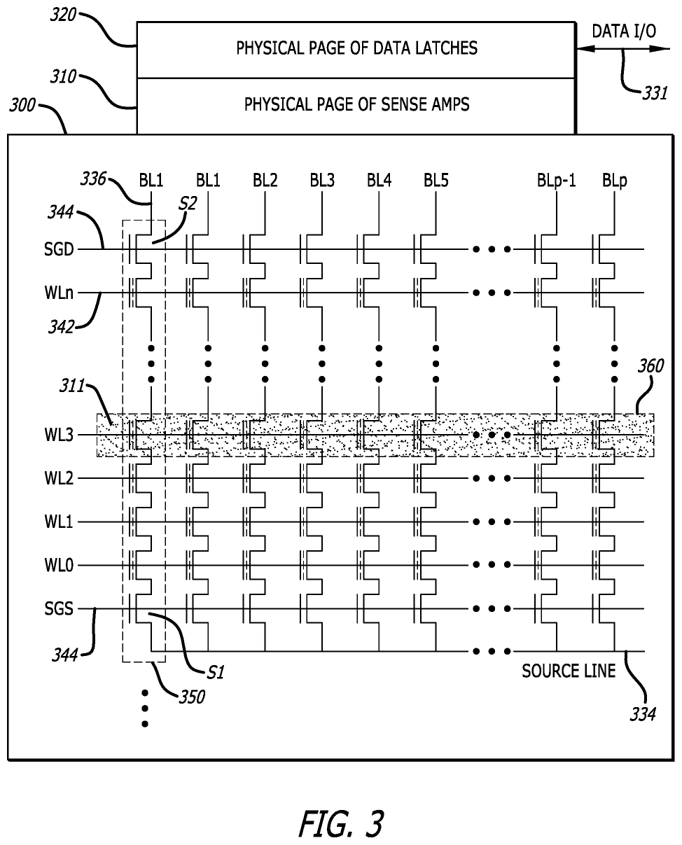

Referring to FIG. 3, a conceptual illustration of a page of memory cells, organized for example in the NAND configuration, being sensed or programmed in parallel in accordance with an embodiment of the disclosure. FIG. 3 conceptually shows a bank of NAND strings 350 within a non-volatile memory device 123 of FIG. 1C. A ‘page’ such as the page 360, is a group of memory cells enabled to be sensed or programmed in parallel. This is accomplished in the peripheral circuits by a corresponding page of sense amplifiers 310. The sensed results are utilized in latches within a corresponding set of data latches 320. Each sense amplifier can be coupled to a NAND string, such as NAND string 350 via a bit line 336. For example, the page 360 is along a row and is sensed by a sensing voltage applied to the control gates of the cells of the page connected in common to the word line WL3. Along each column, each memory cell such as memory cell 311 is accessible by a sense amplifier via a bit line 336. Data in the data latches 320 are toggled in from or out to the memory controller 126 via a data I/O bus 331.

The NAND string 350 can be a series of memory cells, such as memory cell 311, daisy-chained by their sources and drains to form a source terminal and a drain terminal respective at its two ends. A pair of select transistors S1, S2 can control the memory cell chain's connection to the external source via the NAND string's source terminal and drain terminal, respectively. In a memory array, when the source select transistor S1 is turned on, the source terminal is coupled to a source line 334. Similarly, when the drain select transistor S2 is turned on, the drain terminal of the NAND string is coupled to a bit line 336 of the memory array. Each memory cell 311 in the chain acts to store a charge. It has a charge storage element to store a given amount of charge so as to represent an intended memory state. In many embodiments, a control gate within each memory cell can allow for control over read and write operations. Often, the control gates of corresponding memory cells of each row within a plurality of NAND strings are all connected to the same word line (such as WL0. WL1 . . . WLn 342). Similarly, a control gate of each of the select transistors S1, S2 (accessed via select lines 344 SGS and SGD respectively) provides control access to the NAND string via its source terminal and drain terminal respectively.

While the example memory device referred to above comprises physical page memory cells that store single bits of data, in most embodiments each cell is storing multi-bit data, and each physical page can have multiple data pages. Additionally, in further embodiments, physical pages may store one or more logical sectors of data. Typically, the host-computing device 110 (see FIG. 1) operating with a disk operating system manages the storage of a file by organizing the content of the file in units of logical sectors, which is typically in one or more units of 512 bytes. In some embodiments, a physical page may have 16 kB of memory cells being sensed in parallel by corresponding 16 kB of sense amplifiers via 16 kB of bit lines. An example logical sector assigned by the host has a size of 2 kB of data. Thus, a physical page can store 8 sectors if the cells are each configured to store 1 bit of data (SLC). For MLC, TLC, and QLC and other increased density structures, each cell can store 2, 3, 4 or more bits of data, and each physical page can store 16, 32, 64 or more logical sectors depending on the structure utilized.

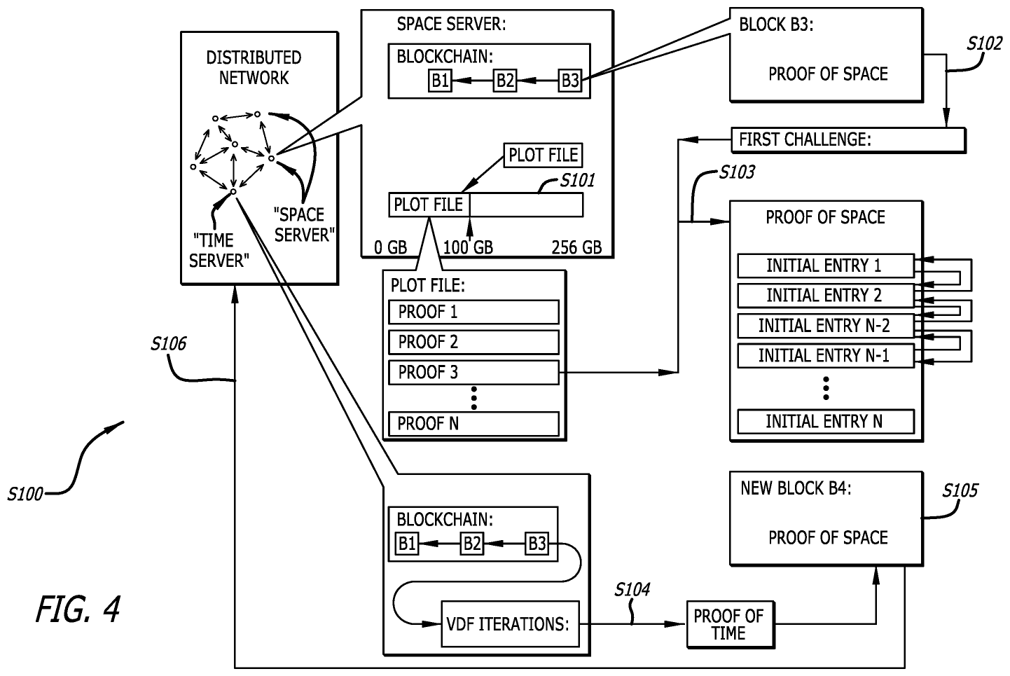

Referring to FIG. 4, a schematic block diagram of an example blockchain data structure for proof of space cryptocurrency process (e.g., Chia plotting) in accordance with an embodiment of the disclosure is shown. As shown in FIG. 4, a method S100 for proof of space cryptocurrency process that combines forward propagation (FP) and backward propagation (BP), hereinafter “Forward-BP” or “Forward-Backward Propagation,” within a distributed network of communicating nodes. The distributed network may include space servers and timer servers for implementing the Forward-BP propagation of the disclosure. Each node within the distributed network can operate one or more space server instances and/or one or more time server instances, therefore a single node can participate in the blockchain by executing the methods S100. Nodes in the distributed network can communicate via gossip protocol (or another decentralized communication protocol) to transfer proofs-of-space, proofs-of-time (e.g., VDF outputs), challenges for new proofs-of-space and proofs-of-time, as well as finished and unfinished blocks of the blockchain. Thus, each node of the distributed network maintains and attempts to extend at least one local copy of the blockchain (or a compressed or concatenated version thereof) to execute steps of method S100.

The blockchain data structure for implementing Forward-BP propagation of method S100 (hereinafter “the blockchain”) includes a canonical chain and a data chain. The space servers and time servers cooperate to generate a blockchain including a set of blocks B1, B2, B3, each block B1, B2, B3 . . . having both a proof-of-space and a proof-of-time responsive to a prior block in the blockchain. Thus, by specifying a proof-of-space and a proof-of-time for each canonical block in the blockchain, the distributed network limits the interval of time during which a space server can generate a proof-of-space, thereby preventing a time-space tradeoff (where a space server attempts to generate a proof-of-space without storing the plot file on drive) that would cause the blockchain to effectively tend toward a proof-of-work system. The data chain includes a series of data blocks, which may represent transaction data and are associated with the canonical chain via cryptographic signatures and hashes corresponding to particular canonical blocks. More specifically, upon creating a canonical block, a space server can generate a corresponding data block based on a hash of the most recent data block in the data chain and sign this data block with a signature based on the proof-of-space of the canonical block.

Further, at step S101, the space server allocates an amount of drive storage for generating proofs-of-space. The space server executes the method S100 to compute proofs of space in order to create canonical and data blocks with which to extend the blockchain. For example, the proof-of-time and proof-of-space for the new block B4 that extends the blockchain follows the completion of the proof-of-space for block B3. A space server in the distributed network can: generate a unique public-private key pair with which to generate plot files and/or sign newly generated blocks, allocate space an amount of drive storage (i.e., by generating plot files occupying space on disk), generate proofs-of-space in response to challenges received via the distributed network, and upon generating a valid proof-of-space to a challenge, generating a canonical block and a data block with which to extend the blockchain. Thus, each space server on the distributed network can cryptographically prove that the space server has allocated unused disk space in order to “win” the privilege to add blocks to the blockchain.

Further, at step 101, the space server can generate a plot file characterized by the amount of drive storage and associated with the space server and store the plot file on a drive accessible by the space server. Thus, the space server can algorithmically generate a set of unique plot files that occupy the allocated drive space accessible by the space server. Each plot file defines a structure that cryptographically verifies its presence on a drive accessible to the space server and prevents malicious nodes from generating proofs-of-space in response to challenges without allocating drive storage (e.g., via a time-space tradeoff attack).

In some embodiments, the space server can generate the plot file by generating a set of tables (e.g., seven tables) representing proofs-of-space based on a plot seed, the set of tables representing proofs-of-space characterized by a resistance to time-space tradeoff attacks. In this implementation, the set of tables includes many individual proofs-of-space (e.g., 4,294,967,296 proofs-of-space for 100 GB of allocated drive space). Thus, the space server can identify a match between a challenge and one of the proofs-of-space represented in the plot file.

Upon allocating the plot file, the space server executes step S102 of accessing a first challenge based on a prior block of the blockchain, block B3, the prior block B3 including a first proof-of-space and a first proof-of-time. Moreover, upon allocating drive space accessible to the space server (e.g., via creation of plot files occupying this drive space), the space server can receive challenges based on a current version of the blockchain in Step S102. Thus, the space server can access or receive the challenge and attempt to look-up the challenge within a plot file within drive storage accessible to the space server. Further, the space server can receive or cryptographically calculate a challenge based on a prior block in the blockchain in order to generate a proof-of-space responsive to the challenge.

At step 103, in response to accessing the first challenge, the space server generates a second proof-of-space based on the first challenge and the amount of drive storage, the second proof-of-space indicating allocation of the amount of drive storage. Thus, the space server can generate the proof-of-space based on the challenge and the amount of drive storage, the proof-of-space indicating allocation of the amount of drive storage; execute a quality function based on the proof-of-space and the challenge to generate a quality characterizing the proof-of-space; and calculate a time delay based on the quality. Thus, when generating a proof-of-space responsive to a challenge, the space server can also calculate a quality of the proof-of-space in order to ascertain an amount of time (as measured by a proof-of-time generated by a time server) sufficient to add the block to the block chain. For example, if the space server calculates a relative quality of the proof-of-space, then the time delay to generate a block including the proof-of-space is relatively short. However, if the space server calculates a relatively low quality, the time delay to generate a block including the proof-of-space is relatively long. Therefore, the space server in the distributed network that generates the highest quality proof-of-space in response to a given challenge is able to generate a block to add to the blockchain first.

The proof-of-space generation includes a forward propagation phase followed by a backward propagation phase. In the forward propagation phase, the space server can execute a depth-dependent cryptographic hash function in order to generate a forward-propagated entry for a subsequent table from a pair of matching entries in the current table in order to account for depth dependent changes in the size of the set of initial entries that corresponds to the pair of matching entries. The space server can execute a cryptographic hash function that collates and/or concatenates the set of initial entries corresponding to the matching pair of entries in order to reduce the amount of temporary storage required to compute a forward-propagated entry via the cryptographic hash function. However, not all entries in a given table of the plot file satisfy the matching condition. Upon completion of the forward-propagation process, the space server can backpropagate through the set of tables of the plot file to remove entries that do not contribute to a final entry in the final table of the plot file. Thus, the space server can reduce the drive space occupied by a single plot file be removing unnecessary data from the final plot file.

Specifically, in the conventional proof-of-space generation in the proof of space cryptocurrency process (e.g., Chia plotting) includes a first phase forward propagation of building a plurality of table of entries, plotting the plurality of table of entries to calculate for matching conditions among the plurality of table of entries, check for matching conditions and sorting the plurality of table of entries. A cipher function is used for plotting the plurality of table of entries and an encryption function is used to match a sought after condition (i.e., data and values useful for finding proofs within the plurality of table of entries), the position and value of the plurality of table of entries are then collated and written to the storage device useful for finding proofs. The conventional proof-of-space generation in the proof of space cryptocurrency process (e.g., Chia plotting) includes a second phase backward propagation of removing data which is not useful for finding proofs so that the final plot is more space efficient. Thus, redundant entries not forming part of the matching condition are dropped and their corresponding positions are adjusted.

Therefore, in the conventional proof-of-space generation in the proof of space cryptocurrency process (e.g., Chia plotting), the plotting scheme is space efficient for final plots but not the plotting process since redundant entries which don't lead to any matches in the table of entries are not dropped until backward propagation. The disadvantage of this scheme is that a large amount of memory or storage space is needed to store all entries until forward propagation. For example, a total memory of 400-500 GB may be needed for one implementation of Chia plotting.

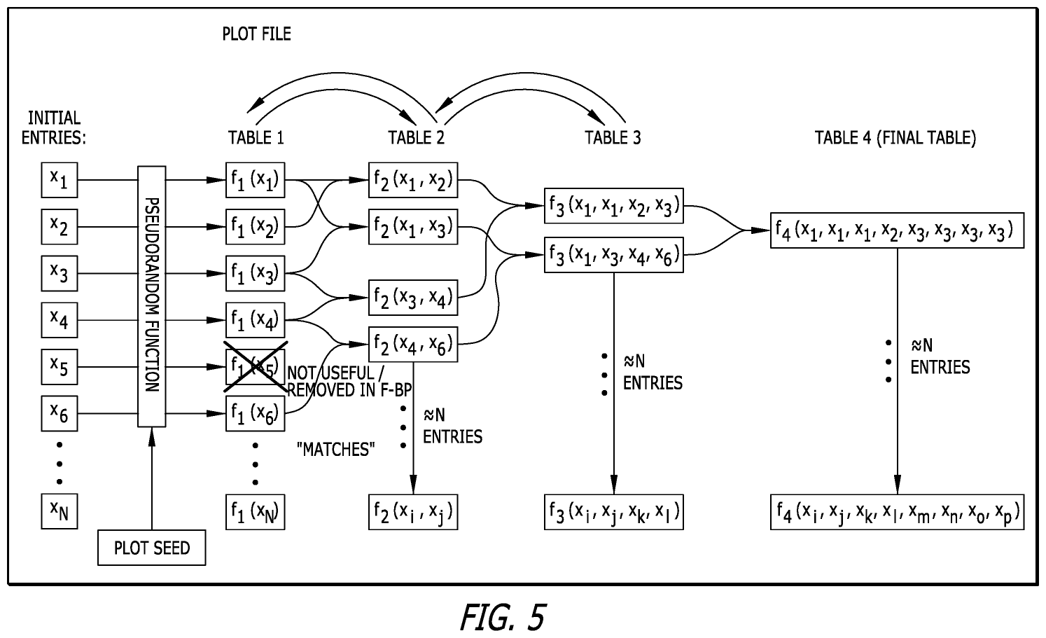

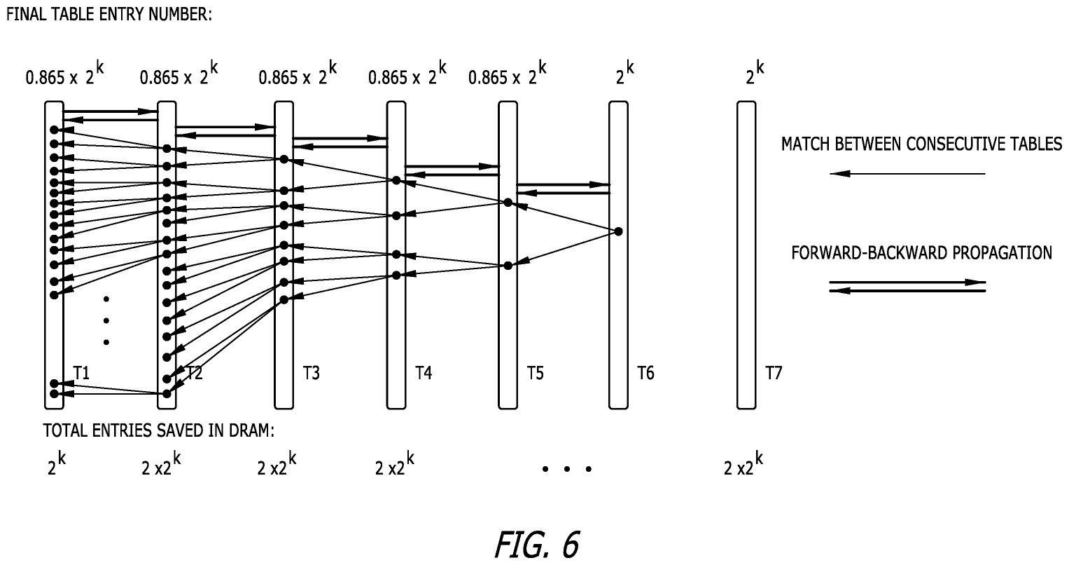

The initial entries 1, 2, . . . N-2, N-1, N undergo a two phase Chia plotting process using Forward-BP propagation of the present disclosure that optimizes the forward propagation of populating the plurality of table of entries by trading of the storage space of the final plots with memory space of the plotting process. As will be described in more detail in FIGS. 5-6, the Forward-BP propagation process eliminates redundant entries during the forward propagation phase by integrating a 1-step backward propagation phase immediately following the forward propagation phase. The Forward-BP propagation process includes a proof-of-space generation having a first data generation stage by forward propagation (e.g., allocating space, generating a plurality of tables of entries, plotting, etc.) immediately followed by a second data verification stage by backward propagation (e.g., determining matching conditions from the challenge, performing proof of space, etc.). As shown in step S103, the plurality of table of entries in the proof of space of block B3 undergo a Forward-BP propagation including a forward propagation phase immediately followed by a 1-step backward propagation phase to eliminate redundant entries in consecutive/adjacent tables while attempting to complete the first challenge and check for matching conditions. Thus, excess or redundant table of entries are immediately dropped during Forward-BP propagation where back propagation happens immediately after each forward propagation, where the back propagation in the Forward-BP propagation is 1-step backward (i.e., only between consecutive tables).

With Forward-BP propagation, the plotting process is more space efficient as a small amount of memory is needed to save entries of adjacent plurality of tables of entries, and correspondingly there is a slight increase of the final plots as the BP is 1-step not 5-step and correspondingly there are more redundant entries. The memory space saved with 1-step backward propagation is sufficient to store 2 consecutive table entries instead of 7 table entries to drop redundant entries. As an example, for a Chia plotting process requiring a total memory of 416 GB for one implementation of Chia plotting, with Forward-BP propagation only 68 GB DRAM may be needed instead of 208 GB DRAM to store temporary table entries for the plotting and the total memory is reduced from 416 GB to 276 GB. In terms of storage space, storage space may increase as there are more redundant entries with backward propagation being 1-step instead of 5-step backward and some redundant entries are not dropped.

At step 104, upon generating a proof-of-space in response to the challenge, the space server can wait to access a proof-of-time indicating or proving that the quality-based time delay corresponding to the proof-of-space has elapsed since generation of the challenge for the proof-of-space. The space server can access a proof-of-time based on the prior blocks B1, B2, B3 of the blockchain and indicate a time delay elapsed after extension of the blockchain with the prior block.

In some embodiments, the space server accesses a VDF output based on the prior block and characterized by a number of VDF iterations corresponding to the quality-dependent time delay or a time-delay greater than the quality-dependent time delay. In another implementation, the space server can receive the proof-of-time (or VDF output) from a time server in the distributed network. Alternatively, the space server can also execute a time server instance and, therefore, execute a VDF function based on the prior block for the quality-dependent time delay to locally generate the proof-of-time.

At step 105, upon generating a proof-of-space and accessing a proof-of-space (e.g., either via a locally executing VDF or a VDF output received via the distributed network), the space server can generate a new block B4 to add to the blockchain including the proof-of-space and the proof-of-time. The space server can generate a new canonical block including the proof-of-space and the proof-of-time and can also generate a data block associated with the new canonical block, the new data block including: a data payload; a cryptographic signature based on the second proof-of-space; and a cryptographic hash of a prior data block. Thus, in response to receiving or accessing a VDF output indicating passage of the quality-based time delay (e.g., indicating a quality-based number of VDF iterations corresponding to the time delay), the space server can generate a new block for both the canonical chain and the data chain, thereby extending the blockchain to securely store new data over the distributed network.

In some embodiments, when the blockchain represents transactions of a cryptocurrency, the space server can include a predetermined (e.g., by the distributed network) reward within a new data block in addition to the buffer of transaction data collected since creation of a prior block. Therefore, a space server can issue itself a predetermined quantity of the cryptocurrency as a transaction within a new data block created by the space server, thereby incentivizing space servers to continually generate new blocks. Thus, the space server can generate a new data block associated with the new canonical block, the new data block including: a data payload comprising transaction data and reward data; a cryptographic signature based on the proof-of-space; and a cryptographic hash of a prior data block.

Referring to FIG. 5, a schematic block diagram of an example plot file in proof of space cryptocurrency process in accordance with an embodiment of the disclosure is shown. As depicted in FIG. 5, the Forward-BP propagation of the present disclosure includes a forward propagation phase by space server that generates a plot file. The plot filed is generated by a series of initial entries xᵢ passed to a plot seed (e.g., pseudorandom function) to generate a series of output entries f₁ in Table 1. Matches between pairs of output entries f₁ are identified based on a matching condition, and, in response to identifying a matching pair of output entries f₁ in Table 1, a cryptographic hash function may be executed based on a pair of initial entries corresponding to the pair of output entries to generate a forward-propagated entry in subsequent Table 2. At Table 2, a backward propagation phase immediately follows to remove excessive or not useful entry f₅ from Table 1. From Table 2, the space server can then, for each subsequent Table 1, 2, 3, 4, etc., in the set of tables, identify matching pairs of entries in the table (derived from entries in a prior table) to generate a forward-propagated entry in a subsequent table based on the initial entries in table one corresponding to the matching pair of entries and remove excessive or not useful output entries f₁, f₂, f₃, f₄, etc., a backward propagation phase immediately following the forward propagation phase.

Referring to FIG. 6, a schematic block diagram of two example phases of proof of space cryptocurrency process in accordance with an embodiment of the disclosure is shown. As depicted in FIG. 6, the Forward-BP method of the present disclosure arrives at a final table entry through a forward propagation phase immediately followed by a backward propagation phase. Again, from the initial table T1, matching entries can be forward-propagated immediately followed by a backward propagation phase to remove excessive or redundant entries in Tables T2, T3, T4, T5 and T6. The total entries saved in DRAM being 2^{k} for T1, and 2×2^{k} for T2-T7 as opposed to the traditional plotting methods that can yield additional entries in DRAM as follows: 2^{k} for T1, 2×2^{k} for T2, 3×2^{k} for T3, 4×2^{k} for T4, 5×2^{k} for T5, 6×2^{k} for T6, and 7×2^{k} for T7, that is redundant entries are kept until a backward propagation method that removes excessive or redundant entries from tables T1-T6. Moreover, in the conventional two-phase forward propagation and backward propagation method, a large amount of memory is needed to store all tale entries during the forward propagation method. Whereas, in the Forward-BP propagation method of the present disclosure, redundant entries are immediately dropped such that a small amount of memory is enough to store entries of adjacent tables.

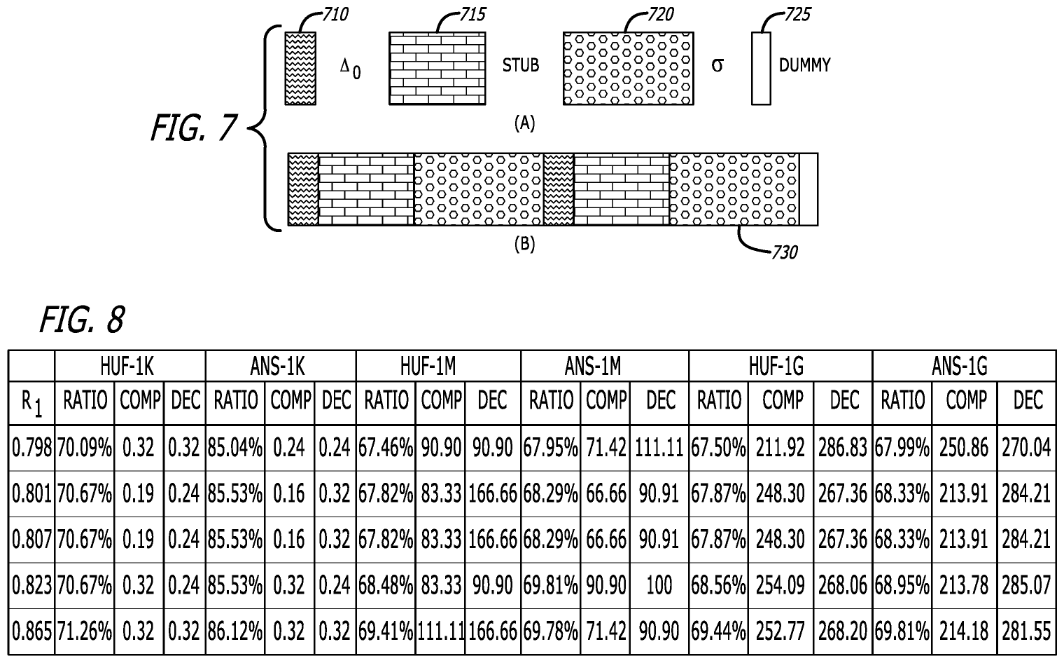

Referring to FIG. 7, a schematic block diagram of an example park storage format and group park storage for proof of space cryptocurrency process in accordance with an embodiment of the disclosure is shown. In many embodiments, the number of entries per park can be increased. This is based on various results depicting the performances of Huffman compression methods with larger file sizes. In additional embodiments, the number of entries per park, k, and the storage size for a compressed park, S, is selected such that the allocated storage has sufficient space to store all compressed entries even in the worst case. For convenience, we use park storage to denote the allocated storage space for compressed park. Note that to efficiently retrieve proofs, the park storage size is often fixed and thus inevitably there may be some space wasted.

More specifically, let μ and σ denote the entropy and standard deviation of δ. That is,

$$μ = {\sum }_{x ∈ {p}_{t}} P ( x ) {log}_{2} P ( x ) , \qquad ( 5 )$$

$$σ = \sqrt{{\sum }_{x ∈ {p}_{t} ( δ = x , {R}_{t} )} P ( x ) {( {log}_{2} P ( x ) - μ )}^{2} ,} \qquad ( 6 )$$

Let Sₑ denote the size of compressed δ and let Sₚ denote the size of one compressed park. As those skilled in the art of information theory will recognize, when Sₑ is a random variable, it follows N (μ, σ), and Sₚ follows N (kμ, \sqrt{kσ}). The park storage size, S, can be selected such that with a high probability, e.g., 99.9%, it has enough space to store all compressed entries, i.e., Pr(S≥Sₚ)>99.9%. That is, the average park storage space per delta, i.e., S/k, should be at least

$$μ + \frac{s}{\sqrt{k}} σ ,$$

where

$$s \geq {Φ}^{- 1} ( \frac{0.99 {9}^{k} - k μ}{k σ} )$$

and Φ is the CDF function of N(0,1). Therefore, a k large to a small s and correspondingly small

$$μ + \frac{s}{\sqrt{k}} σ .$$

to validate this, a number of deltas per park may be changed, i.e., k, in original Chia plotting, and compare the compressed plot sizes with both ANS and Huffman are described in more detail below.

Based on this, as shown in FIG. 7, the group park storage format may also be modified from the original Chia design that uses a fixed park storage format. In FIG. 7, the original format (A) includes each storage park starting with Δ₀ 710, then k stubs 715, then k δs 720, and may end up with some dummy space 725. In a number of embodiments, this design can favor a proof retrieval process as each park starts at a fixed location of disk and its retrieval is simple and efficient.

The default storage park format can be changed in many embodiments to further optimize plot size. As shown in FIG. 7, the proposed group park storage format (B) may include several parks, and starts with qΔ₀, then qk stubs, then qk δs, and some dummy space at the end. The advantage of these embodiments is that we can further reduce average park storage space per delta as each group park storage contains qk entries. As shown in FIG. 11, a comparison of final plot sizes with various parameters, i.e., entries per park k and group park number q illustrate that with appropriate parameters of q and k, it is possible to remove the storage overhead caused by 1-step backward propagation in various embodiments.

Referring to FIG. 8, a table of an example benchmark comparison of Asymmetric Numeral System (ANS) and Huffman for proof of space cryptocurrency process in accordance with an embodiment of the disclosure is shown. In some embodiments, additional techniques may be used to optimize the final plot size via optimizing compression algorithm and the park size and format. FIGS. 8-11 illustrate tables comprising an example benchmark comparison and various parameters of Asymmetric Numeral System (ANS) compression methods compared against Huffman compression engines. These comparisons are shown plotting with different park sizes, prove retrieval performance comparison, and final plot sizes with various parameters for a proof of space cryptocurrency process in accordance with an embodiment of the disclosure.

In some embodiments, the compression phase of plotting (e.g., Chia plotting) may be further optimized by utilizing a Huffman compression engine instead of a Asymmetric Numeral System (ANS) compression engine. The purpose of the conventional compression phase of plotting is to gain the best space efficiency for the final plots. The data is first converted from a 2-dimensional (position, offset) format for table entries to a 1-dimensional line pointer format for better compression. A fixed amount of double pointer formatted data (e.g., 2048) are grouped as a park, and a park is a unit of delta compression input using ANS as the compression engine. However, naively adopting the default compression algorithm, i.e., ANS, the default park size, and the park format increases the plot size by 16% (see FIG. 11).

In certain embodiments we can run a benchmark which can generate data from pₜ(δ=x, Rₜ) for t=1, 2, 3, . . . , 5 and with various lengths to compare compression ratios, compression throughput, and decoding throughput between ANS and Huffman compression methods. From the table depicted in FIG. 8, it can be seen that for pₜ(δ=x, Rₜ), Huffman methods can be much more space efficient than traditional ANS compression methods, especially for small source files (e.g., 1K). Likewise, the advantage appears to vanish with larger source files (e.g., 1G); the compression through a Huffman method is higher than that of an ANS compression method. Additionally, the decompression throughput of a Huffman process is comparable to that of an ANS process.

In some embodiments, the number of entries per park may be increased as empirical results show improved performances of Huffman with larger file sizes (see FIG. 8). Further, the number of entries per park, k, and the storage size for a compressed park, S, is selected such that the allocated storage has sufficient space to store all compressed entries even in the worst case. For convenience, we use park storage to denote the allocated storage space for compressed park. Note that to efficiently retrieve proofs, the park storage size is always fixed and thus inevitably there is some space wasted.

Referring to FIG. 9, a table of an example plot size comparison with ANS/Huffman and different park sizes for proof of space cryptocurrency process in accordance with an embodiment of the disclosures is shown. The number of deltas per park, i.e., k, can be changed within an original Chia plotting system. As a result, compressed plot sizes can be compared with both ANS and Huffman compression methods. An advantage of the embodiments described herein is to further reduce average park storage space per delta, and the disadvantage is that there is some time overhead of the proof retrieval process as more data has to be decompressed to retrieve a single proof.

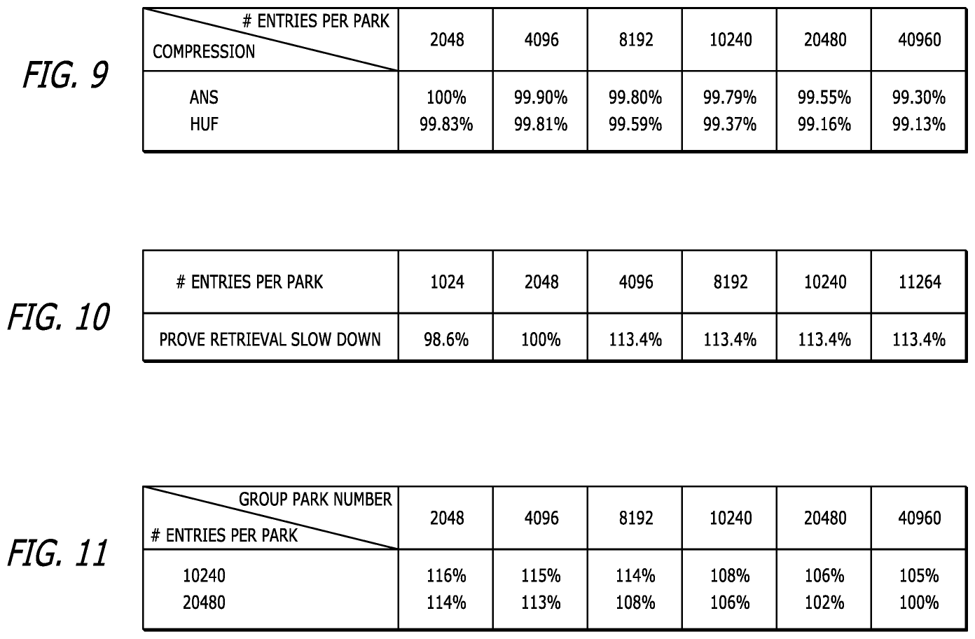

Referring to FIG. 10, a table of an example prove retrieval performance comparison for proof of space cryptocurrency process in accordance with an embodiment of the disclosure is shown. As shown in FIG. 10, the increased time overhead of the proof retrieval part as the number of entries per park increases, where time overhead of the proof retrieval part can increase by 13%. As can be seen, slow down can occur at a low number entries per park, but can become more efficient as the number of entries per park is increased.

Referring to FIG. 11, a table of an example comparison of final plot sizes with various parameters for proof of space cryptocurrency process in accordance with an embodiment of the disclosure is shown. In certain embodiments, as depicted in FIG. 11, the smaller number of entries and/or group park number can significantly decrease the overall efficiency of the plot size. However, as the number of entries per park and the group park number keeps increasing, the final size of the plot becomes equal with traditional methods of plot generation.

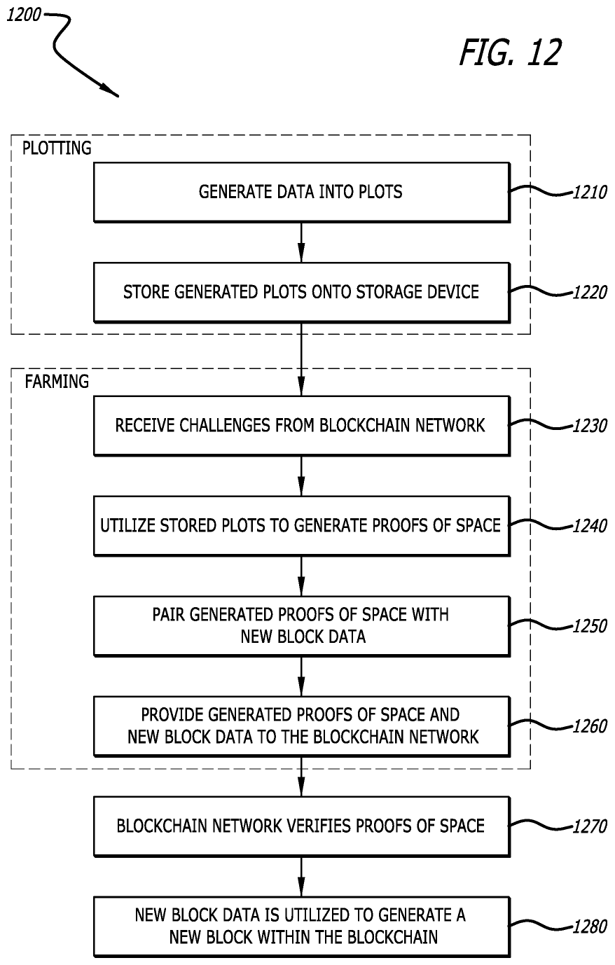

Referring to FIG. 12, a flowchart depicting a process 1200 for mining cryptocurrency utilizing a proof of space consensus method in accordance with an embodiment of the disclosure is shown. As discussed above, the mining of cryptocurrency can come in many forms. In a growing number of applications, cryptocurrency that uses a consensus method of proof of space can be utilized as an alternative to the currently more popular proof of work method. In many embodiments, these proof of space methods include a first data generation stage and a second data verification stage.

One example of a blockchain-based cryptocurrency that utilizes proof of space as a consensus method is Chia. Chia is centered on creating (i.e., “plotting”) large quantities of proof of space consensus data via a data generation process that is formatted into one or more “plots.” These plots are then stored on a hard drive for future accessing by the online Chia blockchain network. The plots comprise a series of hashed tables which may be accessed by the Chia network in response to a challenge posed by the network. This process of storing the plots and providing them to the online Chia network for challenge processing is called “farming.”

In a typical proof of space blockchain process 1200 the plotting stage can begin by generating data into plots (block 1210). Although Chia utilizes plots, some embodiments may be able to be formatted for use within other proof of space-based blockchain-based systems. In many embodiments, the generation of plot data involves the creation of a plurality of tables comprising cryptographic hashes that may be nested, self-referential, or otherwise related. In various embodiments, the hashes created through a back propagation method and are then sorted and compressed throughout the tables. The plots are completed and stored onto a storage device (block 1220). This generation of plots creates a lot of input and output processes within the storage device and benefits from high-speed storage devices. This results in many users utilizing SSDs for plotting operations. However, the nature of many SSDs and their finite endurance leads to many users copying the generated plots to a secondary storage device that is more configured for long-term storage.

The farming stage of proof of space consensus blockchain system comprises all of the remaining steps. Farming can begin by receiving one or more challenges from the blockchain network (block 1230). The exact type of challenge may vary based on the cryptocurrency process used. For example, the challenge may be a problem that must be solved within a certain time and/or in a particular format. The process 300A can utilize the stored plots to generate proofs of space (block 1240). This step is described in more detail within the discussion of FIG. 3B. These proofs of space are required of the challenge answers that allow the user to attempt to add their contribution to the blockchain and reap a reward. In a variety of embodiments, the generated proofs of space are paired with new block data (block 1250). New block data can include a proposed data block to add to the blockchain. Those skilled in the art will understand that this new block data may be comprised of sub-blocks or any other proposed block data as required by the blockchain being utilized.

The paired proofs of space and new block data is transmitted onto the blockchain network (block 1260). The transmitted data is not automatically added to the blockchain but needs to satisfy one or more requirements as more than one user on the network may have submitted a valid proof to the challenge. During the selection of a potential new block, the blockchain network will verify the submitted proofs of space (block 1270). This can be done in a variety of ways depending on the exact blockchain used. Once the blockchain network has settled on a particular block candidate that was submitted, the new block data is utilized to generate new block within the blockchain (block 1280).

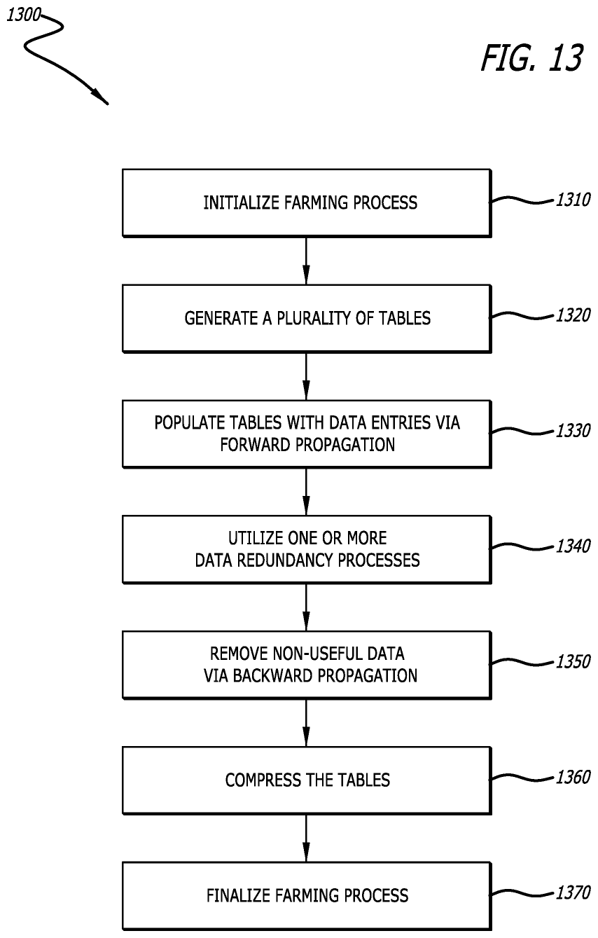

Referring to FIG. 13, a flowchart depicting a process 1300 for generating plots more efficiently in accordance with an embodiment of the disclosure is shown. In many embodiments, the process 1300 can commence upon initialization of the farming process (block 1310). Typically, this can occur when a host-computing device utilizes a storage device to create one or more new plots for a proof of space cryptocurrency system. In a number of embodiments, the process 1300 can generate a plurality of tables (block 1320). For example, within a Chia cryptocurrency system, many nodes will generate a plot with seven tables.

In more embodiments, the process 1300 can populate tables with data entries via forward propagation (block 1330). Methods for populating these tables is described above. Additional methods are also available within standard cryptocurrency methods as those skilled in the art will recognize. In a variety of embodiments, the process 1300 can utilize one or more data redundancy processes (block 1340). Example data redundancy processes are described above. However, any method of determining and removing unused and/or unneeded data can be utilized, depending on the application. Often, the one or more data redundancy processes are done during the forward propagation step.

In further embodiments, the process 1300 can remove non-useful data via a backward propagation step (block 1350). In some embodiments, this is done via a 1-step backwards method. This is typically done in comparison to a full 5-6 step backwards method of traditional plotting methods. In additional embodiments, this forward and backward propagation can repeat until a sufficient number of tables have been filled. In more embodiments, the process 1300 can compress the tables (block 1360). Compression methods are described above. In certain embodiments, compression can be done after each forward and backward propagation step, while in other embodiments, compression can be done after the forward and backward propagation steps have completed populating all of the available tables with entries. Upon completion of the compression, the process 1300 can finalize the farming process (block 1370).

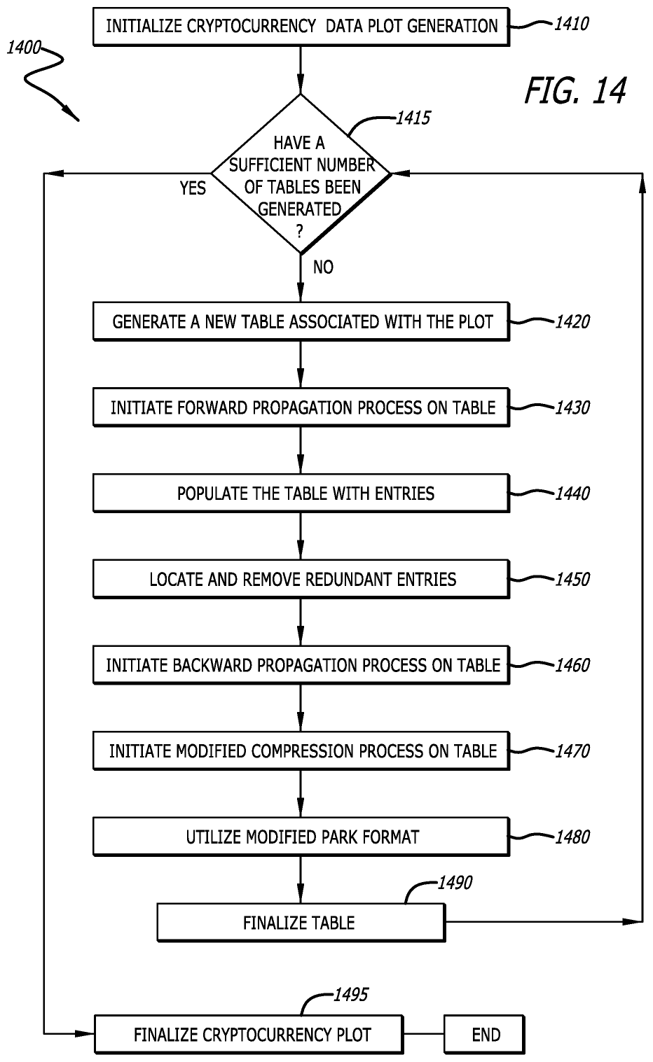

Referring to FIG. 14, a flowchart depicting a process 1400 for efficiently generating cryptocurrency tables in a proof of stake cryptocurrency system in accordance with an embodiment of the disclosure is shown. In many embodiments, the process 1400, can commence by initializing cryptocurrency data plot generation (block 1410). During the plot generation process, a plurality of tables can be generated. The process 1400 can determine if a sufficient number of tables have been generated (block 1415). If enough tables have been generated, then the process 1400 can finalize the cryptocurrency plot before ending (block 1495).

However, when another table is needed, the process 1400 can generate a new table associated with the plot (block 1420). Often, the table is configured to hold a plurality of entries, which can be pointers or data associated with other entries in other tables but may simply contain data. Once the table has been generated, the process 1400 can initiate a forward propagation process on the table (block 1430). During the forward propagation process, the table can be populated with entries (block 1440).

In a number of embodiments, the process 1400 can locate and remove redundant or unused entries within the generated table (block 1450). Subsequently, the process 1400 can initiate a backward propagation process on the table (block 1460). As stated above, various embodiments may utilize a one-step backward process that looks to the previous table to make decisions on removing unused or unneeded entries within the tables. Eventually, the process 1400 can initiate a modified compression process on the table (block 1470). As described above, the modified compression process can include utilizing a different or non-typical compression method such as, but not limited to, a Huffman-based compression method.

In further embodiments, the process 1400 can utilize a modified park format (block 1480). As described above, different levels of compression and efficiency can be achieved through changing the typical park format. Therefore, modifying the park format to best suit the needed compression and/or final size of the plot is often done. The process 1400 can finalize the table within the plot (block 1480). Once finalized, the process 1400 can determine if a sufficient number of tables have been generated (i.e., is another table still needed) (block 1415). If not, the process 1400 can finalize the cryptocurrency plot prior to ending the process (block 1495).

Information as herein shown and described in detail is fully capable of attaining the above-described object of the present disclosure, the presently preferred embodiment of the present disclosure, and is, thus, representative of the subject matter that is broadly contemplated by the present disclosure. The scope of the present disclosure fully encompasses other embodiments that might become obvious to those skilled in the art, and is to be limited, accordingly, by nothing other than the appended claims. Any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for solutions to such problems to be encompassed by the present claims. Furthermore, no element, component, or method step in the present disclosure is intended to be dedicated to the public regardless of whether the element, component, or method step is explicitly recited in the claims. Various changes and modifications in form, material, work-piece, and fabrication material detail can be made, without departing from the spirit and scope of the present disclosure, as set forth in the appended claims, as might be apparent to those of ordinary skill in the art, are also encompassed by the present disclosure.

What is claimed is:

1. A device comprising:
a processor;
a memory array comprising a plurality of memory devices; and
a controller communicatively coupled to the memory array;
a proof of space cryptocurrency logic configured to:
utilize a proof of space cryptocurrency process comprising a first data generation stage and a second data verification stage;
wherein during the data generation stage, one or more data redundancy processes are utilized to reduce the size of data required during the first data generation stage.

2. The device of claim 1, wherein the cryptocurrency process is a Chia and the first data generation stage is a plotting stage.

3. The device of claim 2, wherein the plotting stage comprises generating a plurality of tables of entries.

4. The device of claim 3, wherein the plurality of tables comprises seven tables of entries.

5. The device of claim 4, wherein entries within one table reference at least one entry in another table.

6. The device of claim 5, wherein the data stored within a table is in a two-dimensional format.

7. The device of claim 6, wherein the one or more redundancy processes include a compression method.

8. The device of claim 7, wherein the compression method converts data from a two-dimensional format to a one-dimension format.

9. The storage device of claim 4, wherein the one or more redundancy processes include a multi-directional propagation method.

10. The storage device of claim 9, wherein the multi-directional propagation method includes a forward and backward propagation wherein a backward propagation directly after each forward propagation.

11. The device of claim 10, wherein the forward and backward propagation method identifies and removes redundant entries within the plurality of tables.

12. A method comprising:
utilizing a proof of space cryptocurrency process comprising a first data generation stage and a second data verification stage;
wherein during the data generation stage, one or more data redundancy processes are utilized to reduce the size of data required during the first data generation stage.

13. The method of claim 12, wherein the first data generation stage comprises generating a plurality of tables of entries.

14. The method of claim 13, wherein the one or more redundancy processes comprises at least one propagation step and a compression step.

15. The method of claim 14, wherein the one or more redundancy processes comprises at least a forward propagation step, a backward propagation step, and a compression step.

16. The method of claim 15, wherein the backward propagation step is a one-step backward propagation step.

17. The method of claim 15, wherein, in response to completing the one or more redundancy processes, at least one table is redundant.

18. The method of claim 15, wherein the compression step utilizes a Huffman compression method.

19. The method of claim 15, wherein the compression method utilizes a modified park storage format.

20. A device comprising:
a processor;
a memory array comprising a plurality of memory devices; and
a controller communicatively coupled to the memory array;
a proof of space cryptocurrency logic configured to generate cryptocurrency by:
generating a plot within the memory array, comprising:
a plurality of tables populated with data entries which are processed utilizing at least:
a forward propagation step wherein one or more redundant entries are removed;
a backward propagation step; and
a compression step; and
retrieving, in response to a challenge, one or more proofs of ownership of the generated plot.
